(19) United States
(12) Patent Application Publication
(10) Pub. No.: US 2006/0118933 A1
(43) Pub. Date: Jun. 8, 2006

(54) Stackable frames for packaging microelectronic devices

(75) Inventor: Belgacem Haba, Saratoga, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/284,066

(22) Filed: Nov. 21, 2005

Related U.S. Application Data
(60) Provisional application No. 60/633,761, filed on Dec. 7, 2004.

(51) Int. Cl. H01L 23/02

(52) U.S. Cl. 257/678

(57) ABSTRACT

A frame is provided for packaging a microelectronic device. The frame is formed from a unitary member, electrically conductive device-attachable pads, and terminals in electrical communication with the device-attachable pads. The unitary member includes a base section, first and second wall sections each extending from the base section, and first and second roof surfaces supported by the first and second wall sections, respectively. The base section has an interior surface having electrically conductive device-attachable pads thereon. The terminals are typically located on the first and second roof surfaces. Optionally, first and second cantilevered sections extend from the first and second wall sections, respectively, toward each other. The frame is typically stackable. Also provided are microelectronic packages and methods for producing microelectronic packages.

### CROSS-REFERENCE TO RELATED APPLICATIONS

The present invention claims the benefit of the filing date of U.S. Provisional Patent Application No. 60/633,761, filed Dec. 7, 2004, the disclosure of which is hereby incorporated by reference herein.

### FIELD OF THE INVENTION

The invention relates generally to frames for packaging microelectronic devices. In particular, the invention relates to stackable frames having optional cantilevered sections for packaging microelectronic devices. Also provided are methods for packaging microelectronic devices, microelectronic packages, and multi-device microelectronic assemblies.

### BACKGROUND OF THE INVENTION

Microelectronic devices such as semiconductor chips are often provided in packages that serve a number of purposes. For example, a microelectronic package may provide physical and/or chemical protection to the microelectronic device. In addition, the package may provide a convenient vehicle for mounting and electrically connecting the microelectronic device. For example, semiconductor chips typically are flat bodies having generally planar front and rear surfaces, with contacts disposed on the front surface connected to the internal electrical circuitry of the chip itself. Semiconductor chips typically are provided in microelectronic packages which define terminals that are electrically connected to the contacts of the chip itself. The package may then be connected to test equipment to determine whether the packaged device conforms to a desired performance standard. Once tested, the package may be connected to a larger circuit, e.g., of an electronic product.

Microelectronic devices have been trending to a decreased size and greater functionality. Accordingly, microelectronic packages have also been trending toward a smaller size and a finer pitch in their inputs and outputs (I/O). For example, early microelectronic devices have been packaged using metal lead-frames. Such packages typically have lead counts of about 8 to about 48 contacts having a pitch of about 1.78 to about 2.54 mm. In contrast, chip-scale packages (CSP) typically have a footprint that is only slightly larger than their associated device. The substrate contacts may have a pitch of 0.8 mm or less. In some instances, CSPs have as low as 0.4 mm pitch.

In some instances, packages employing a flip-chip configuration may be even more compact than CSPs. In this configuration, the front or contact-bearing surface of the microelectronic device faces towards a connection structure. Each contact on the device is joined by a solder bond to a corresponding contact pad on the connection structure, by positioning solder balls on the connection structure or device, juxtaposing the device with the connection structure in the front-face-down orientation, and momentarily reflowing the solder. Unlike the typical CSP configuration, wire or lead bonds are not required. As a result, the package occupies an area of the connection structure no larger than the area of the chip itself. In some instances, the substrate associated with a flip-chip package may have a smaller area than the device bonded thereto.

To provide even greater functionality, a plurality of microelectronic devices may be packaged together. In some instances, microelectronic devices having different functionality may be packaged together for form a system-in-package (SiP). Alternatively, devices having substantially similar functionality, e.g., memory chips, may be packaged together to provide greater capacity, increased speed, and/or improved performance. In either case, the footprint of the package may be reduced by stacking the microelectronic devices. Patents describing stacked packaging of microelectronic devices include, for example, U.S. Pat. Nos. 5,861,666, 6,121,676, 6,225,688, 6,465,893, and 6,699,730.

Nevertheless, there exist further opportunities in the art to provide alternatives and improvements for compact microelectronic device packaging applications, particularly those technologies that exhibit a simple design, are easily manufactured, and allow for facile stacking of microelectronic devices.

### SUMMARY OF THE INVENTION

One aspect of the invention provides a frame for packaging a microelectronic device. The frame is formed from a unitary member, electrically conductive device-attachable pads, and terminals in electrical communication with the device-attachable pads. The unitary member includes a base section, first and second parallel wall sections each extending perpendicularly from the base section, and first and second substantially planar roof surfaces facing away from the base section and supported by the first and second wall sections, respectively. The base section has opposing interior and exterior planar base surfaces, and the electrically conductive device-attachable pads are exposed at the interior base surface. The terminals are typically located on the first and second roof surfaces. However, some or all terminals may be provided on other surfaces as well. For example, one or more terminals may be provided on the exterior base surface.

Typically, the unitary member further comprises first and second cantilevered sections extending from the first and second wall sections, respectively, toward each other. Accordingly, the unitary member may have a C-shape. In addition, the cantilevered sections may support the roof surfaces. Furthermore, the roof surfaces may be substantially coplanar with one another.

To provide systematic addressability, the device-attachable pads may be arranged in a pad array. Similarly, the first and second terminals may be arranged in first and second arrays, respectively. The first and second arrays may exhibit mirror symmetry. In some instances, the entire frame exhibits mirror symmetry.

The frames according to this aspect of the invention may be stackable. A mechanism may be provided for aligning the frame for stacking. For example, at least one set of mating features may be included to facilitate stacking. Such mating features may be located on the exterior surface of the base and at least one roof surface. In addition, when the frame is constructed such that the exterior base surface faces a roof surface of another frame, male and female mating features may be provided on the base and roof surfaces, respectively. Notably, the male and female mating feature may be swapped in position. Furthermore, both male and female mating features may be provided on a single surface.

Electrical communication between any terminal and any device-attachable pad may be routed through any of a number of ways. In some instances, an electrical path may be located at least partially within the unitary member. Alternatively, the path may be exposed and/or located entirely on a surface of the unitary member. In some instances, at least portions of the path may avoid physical contact with the unitary member. Furthermore, the electrical path may represent a portion of a lead-frame.

Polymeric materials may be advantageously used to form the inventive frame. For example, a molded plastic may be used to provide structural support or serve some other function for the frame. Single and/or double-metal-clad sheets may be advantageously used as well.

A further aspect of the invention provides a microelectronic package that includes a frame and a microelectronic device electrical communication therewith. Typically, the microelectronic device has opposing front and rear surfaces separated by a device height and a plurality of electrical contacts on the front surface. For example, the microelectronic device may be or include a semiconductor chip.

While the frame as described above may be used to form the inventive package, other frames may be used as well. However, the roof surfaces of any frame used are typically separated by a gap sized to allow through passage of the device. Optionally, the gap is sized to allow through passage of the device while the front surface of the device is parallel to the interior base surface. In certain embodiments, the wall sections may be no more than twice the device height.

Typically, the device is mounted to interior base surface of the frame. In some instances, the device is positioned such that its front surface faces towards the interior base surface. For example, the device may be rigidly attached to the frame in a flip-chip configuration. Alternatively, the device may be positioned such that its front surface faces away from the interior base surface. In any case, the device may be wire bonded or lead bonded to the frame. Wire or lead bonding allows the device to be movably disposed relative to the device-attachable regions to a substantial fatigue relieving degree.

A plurality of microelectronic packages may be assembled in electrical communication with each another. For example, a plurality of substantially identical microelectronic packages may be stacked.

Thus, the invention also provides a method for producing a microelectronic package. A frame as described above may be electrically attached to electrical contacts on a front surface of a microelectronic device so as to provide electrical communication to the device-attachable pads on the interior surface of the frame. Regardless whether the electrical contacts are rigidly or movably attached to the device-attachable pads, an electrically insulating material may be introduced between the microelectronic device and the base section of the frame. The electrically insulating material may be rigid or compliant depending on whether attachment of the electrical contacts to the device-attachable pads is rigid or movable.

### BRIEF DESCRIPTION OF THE DRAWINGS

FIGS. 1A and 1B, collectively referred to as FIG. 1, illustrate in perspective view a microelectronic device in an exemplary frame of the invention that employs a metal-clad sheet. FIG. 1A depicts the placement of the device in the frame, and FIG. 1B depicts an assembly of stacked packages of identical construction.

FIG. 2 depicts in side view an assembly similar to that depicted in FIG. 1B and electrical connections associated therewith.

FIGS. 3A and 3B, collectively referred to as FIG. 3, illustrate an exemplary frame of the invention having a locking mechanism. FIG. 3A shows the frame in perspective view. FIG. 3B shows in side view an assembly of stacked packages formed from identical frames.

FIGS. 4A and 4B, collectively referred to as FIG. 4, illustrate in side view exemplary packages that include lead-frames. FIG. 4A shows a single package, and FIG. 4B shows an assembly of stacked packages.

FIG. 5 depicts in side view an exemplary frame of the invention in a first alternative shape.

FIG. 6 depicts in side view an exemplary frame of the invention in a second alterative shape.

### DETAILED DESCRIPTION

Before describing embodiments of the present invention in detail, it is to be understood that the invention is not limited to specific microelectronic devices or types of electronic products, as such may vary. It is also to be understood that the terminology used herein is for the purpose of describing particular embodiments only, and is not intended to be limiting.

As used in this specification and the appended claims, the singular article forms “a,” “an,” and “the” include both singular and plural referents unless the context clearly dictates otherwise. Thus, for example, reference to “a set of mating features,” includes a plurality of sets of mating features as well as a single set of mating features, reference to “a microelectronic device” includes a single device as well as a combination of devices, and the like.

In addition, terminology indicative or suggestive of a certain spatial relationship between elements of the invention is to be construed in a relative sense rather an absolute sense unless the context clearly dictates to the contrary. For example, the term “roof” as used to describe a surface of a unitary frame does not necessarily indicate that the surface represents the uppermost portion of the frame. Similarly, the term “base” as used to describe a section of a unitary frame does not indicate that the section is located at the bottom of the frame. Accordingly, a roof surface of a unitary frame may lie above, below, or at the same level as a base section of the same frame depending on the frame's orientation.

Thus, the invention provides for the packaging of a microelectronic device. A frame is provided that is formed form a unitary member within which the device is typically positioned. The frame includes a base section, wall sections, and roof surfaces. The base section has opposing interior and exterior base surfaces and electrically conductive pads on the interior base surface to which the device, or more specifically, a plurality of electrical contacts thereof, is attached. Each wall section extends from the base section, and each roof surface is supported by a corresponding wall section. The roof surfaces face away from the base section and contain terminals in electrical communication with the electrically conductive pads.

The frames of the invention are typically stackable. Accordingly, a plurality of substantially identical microelectronic packages may be stacked to form a multi-device assembly. Similarly, as described in detail below, an alignment mechanism may be provided for aligning the frame for stacking such as mating features. Such mating features may be located on the exterior surface of the base and at least one roof surface. The locations of such features are not critical, and male and female mating features may be swapped in position. In some instances, both male and female mating features may be provided on a single surface. Cantilevered sections may be provided to support roof surfaces and/or facilitate stacking.

The invention also provides a method for producing a microelectronic package. A frame as described above may be electrically attached to electrical contacts on a front surface of a microelectronic device so as to provide electrical communication to the device-attachable pads on the interior surface of the frame. Regardless whether the electrical contacts are rigidly or movably attached to the device-attachable pads, an electrically insulating material may be introduced between the microelectronic device and the base section of the frame. The electrically insulating material may be rigid or compliant depending on whether attachment of the electrical contacts to the device-attachable pads is rigid or movable.

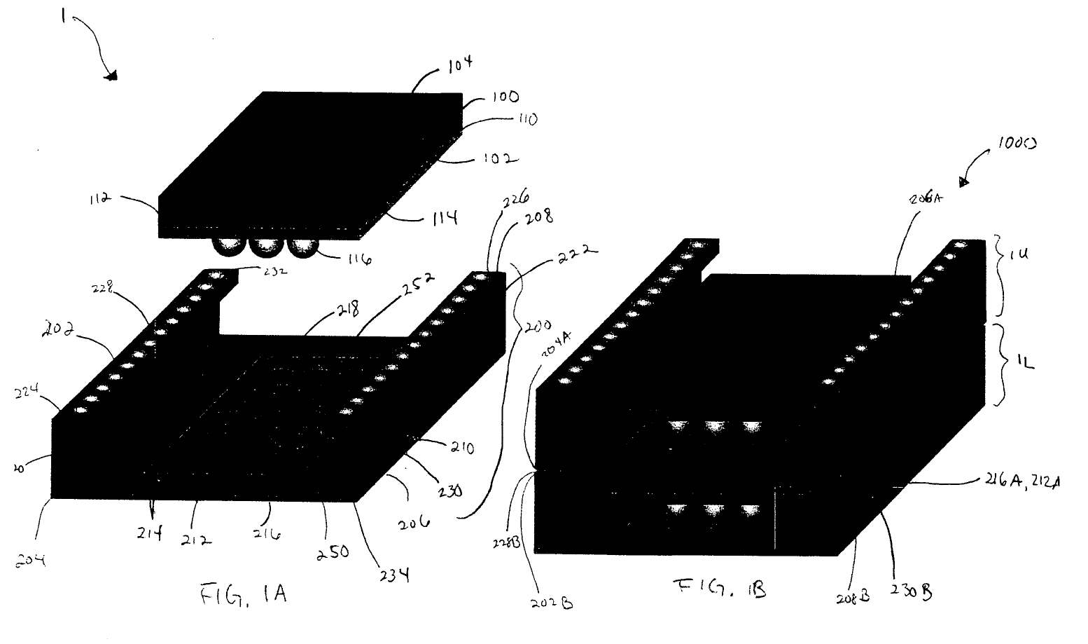

FIG. 1 depicts in perspective view a microelectronic device in an exemplary frame of the invention the employs a metal-clad sheet that may be either single-sided or double-sided. As with all figures referenced herein, in which like parts are referenced by like numerals, FIG. 1 is not to scale, and certain dimensions may be exaggerated for clarity of presentation. As shown, a package 1 may be formed from a microelectronic device 100 and a frame 200. The microelectronic device 100 is generally depicted as having opposing front and rear major surfaces indicated at 102 and 104, respectively. The front and rear surfaces are substantially planar, rectangular in shape, and parallel to each other. The front surface 102 of the microelectronic device 100 includes a plurality of electrical contacts (not shown). In some instances, the electrical contacts may be arranged in an ordered arrangement, i.e., an array. Exemplary arrays types include rectilinear grids, parallel stripes, spirals, and the like.

The microelectronic devices of the invention may take any of a number of forms, including, but not limited to, the form of a chip, or a wafer. As discussed above, the device typically has opposing front and rear surfaces, wherein the front surface provides electrical accessibility. However, microelectronic devices of any geometry may benefit from the invention.

In addition, the invention may be used in conjunction with microelectronic devices used for any of a number of applications, including, for example, semiconductor chips, micro-electromechanical systems (MEMS), optical devices, and microfluidic devices. Often, the devices are formed from a semiconductor. For example, the semiconductor devices may include a single crystalline material consisting essentially of a single element, e.g., Si or Ge, or a compound semiconductor, e.g., a III-V semiconductor such as GaAs. The presence or absence of dopants is not critical to the invention. Alternatively, the semiconductor member may be comprised of a multicrystalline or amorphous semiconductor material such those that often used in photovoltaic applications. Furthermore, the device may be constructed to contain or exclude specific feature according to the intended use of the device. For example, when the device is not intended for optical applications, the device may contain no optically sensitive and/or emitting element.

The microelectronic device 100 in FIG. 1A is a part of a unit that also includes an optional substrate 110. The substrate 110 has first and second surfaces, indicated at 112 and 114, respectively, such that the front surface 102 of the device 100 faces the first surface 112 of the substrate 110. A plurality of electrically conductive members in form of an array of balls 116 are provided on the second surface 114 of the substrate 110. The balls 116 are electrically connected to the electrical contacts of the device. As discussed in detail below, the substrate 110 may be used to ensure that the device 100 is movable relative to the frame 200 to relieve stresses caused by differences in thermal expansion of different materials associated with the package and to provide substantial fatigue relief when the package undergoes thermal cycling.

The frame 200 is shown as a unitary C-shaped item having four ninety-degree folds (or edges), indicated at 202, 204, 206, and 208. The frame includes a metal-clad sheet 210 and an optional C-shaped supporting structure 250. The sheet 210 is wrapped against the supporting structure 250 such that the sheet conforms generally to the shape of the exterior surface of the supporting structure. Accordingly, the sheet 210 also has a C-shape, and includes a base section 212 located between folds 204 and 206. The base section is shown having opposing interior and exterior surface, indicated at 214 and 216, respectively. The interior and exterior surfaces 214, 216 are planar and parallel to each other. A plurality of electrically conductive device-attachable pads 218 are provided on the interior surface 214. The pads 218 are arranged in an array that exhibits spatial correspondence to the position of the substrate balls 116. Alternatively, the device-attachable pads may be arranged in a pad array to provide systematic addressability, regardless whether the pad array exhibits correspondence to the substrate balls. Notably, a window 252 is provided through the support structure 250, thereby providing access to pads 218 for electrical connections. That is, pads 218 are exposed through window 252.

The sheet 210 also includes parallel wall sections and optional coplanar cantilevered sections. First and second parallel wall sections, indicated at 220 and 222, respectively, coextend perpendicularly from base section 212. The first wall section is located between folds 202 and 204, and the second wall section is located between folds 206 and 208. First and second inward cantilevered sections, indicated at 224 and 226, respectively, extend toward each other and perpendicularly from first and second wall sections 220, 222, respectively. More specifically, sections 224 and 226 extend from 90-degree folds 202 and 208, respectively. The cantilevered sections each terminate at an edge that defines a gap that separate the cantilevered sections. A first substantially planar roof surface 228 is supported by cantilevered section 224, and a second substantially planar roof surface 230 is supported by cantilevered section 226. As shown, the roof surfaces 228 and 230 are coplanar.

Terminals on the inventive frame may be arranged in an array. For example, terminals may be arranged in a linear array, i.e., a plurality of colinear features having equidistant neighboring features. As shown, a first linear array of first terminals 232 is located on the first roof surface 228. Similarly, second terminals 234 are provided in a second linear array on the second roof surface 230. Optionally, the first and second linear arrays exhibit mirror symmetry. In some instances, the entire frame and the terminals exhibits mirror symmetry.

The terminals 232, 234 electrically communicate with the device attachable pads 218. Because the terminals 232, 234 and the pads 218 are located on different major surfaces of the metal-clad sheet 210, windows or vias (not shown) extending through the metal-clad sheet 210 may be used to establish such electrical communication. However, electrical communication does not have to be travel along an electrical path that extends through the sheet.

The package 1 may be assembled by placing the unit that includes the microelectronic device 100 and the substrate 110 in electrical communication with the frame 200. For example, the balls 116 of the unit may be soldered to the pads 218 of the frame. As a result, the microelectronic device 100 may be electrically accessible through first and second terminals 232, 234.

As depicted in FIG. 1, the device 100 is indirectly mounted to interior base surface 214. That is, the microelectronic device 100 is electrically connected to substrate 110, which are in turn connected to frames 200. However, other mounting and/or spatial relationships are possible between the microelectronic device and the frame. In some instances, the device may be directed mounted to the interior base surface of the frame without an intermediary connection to a substrate.

In addition, while FIG. 1 depicts a package wherein a microelectronic device is placed “face-down” relative to the interior face surface, the invention allows the device to be positioned placed “face-up” as well. A face-down orientation allows for rigid electrical attachment of the device contacts to the pads of the interior base surface in a flip-chip configuration. A face-up orientation, on the other hand, facilitates wire or lead bonding. In some instances, contacts are provided are both front and rear surface of the microelectronic device.

It should be noted that differences between the coefficient of thermal expansion (CTE) between the microelectronic device and the frame may cause the device contacts and the device-attachable pads of the frame to be displaced to a different degree under thermal cycling conditions. Thus, when the contacts are rigidly bonded to the pads to establish electrical communication therebetween, it is preferred that the materials of the frame be selected such that it has a similar or identical CTE to that of the device so stress and fatigue imposed on the bonds, e.g., due to thermal cycling, are minimized.

Alternatively, the device contacts may be bonded to frame pads in a manner that allows for movement between the device and the frame. This may involve using wire or lead bonds. When a substrate or other item is positioned between the microelectronic device and the base section of the frame, the substrate or other item may comprise a compliant material to allow the device to be displaced relative to the device-attachable pads. As a result, substantial fatigue relief is provided as a result of movability between the device contacts and the frame pads. Exemplary compliant materials include elastomers, foams, gels or other materials commonly regarded as being “soft” over a wide range of temperatures. In addition, materials such as thermoplastics or thermosetting polymers having elastic modulus which decreases substantially at temperatures which may be above room temperature but within the ranges encountered in service or under extreme thermal conditions which may be imposed by the environment. For example, compliant materials used may undergo a substantial reduction in elastic modulus and/or shear modulus at temperatures on the order of 100° C.

It should be noted that the term “substantial” as used to describe the term “fatigue relief,” refers, among other things, to the increase in the average number of cycles for an electrical path to failure by at least two-fold as compared to the cycles for an electrical path that undergoes fatigue. Preferably, the average number of cycle to failure is increased by ten-fold. The terms “substantial” and “substantially” are used analogously in other contexts involve an analogous definition.

To form the assembly, pick-and-place technologies may be employed. For example, robotic or other apparatuses may be used to place the microelectronic device 100 in the frame 200. However, certain frame construction considerations may significantly contribute to ease in device placement and/or mounting. For example, as depicted in FIG. 1, the roof surfaces 228 and 230 may be separated by a gap sized to allow through passage of the device while the front device surface 102 is parallel to the interior base surface. That is, the gap is wider than the width and/or length of the device 100.

Regardless how any of the inventive packages are formed, it is generally desirable to provide compact microelectronic packages assemblies. In general, the frame may have a footprint that occupies an area that is no greater than about twice of that of the front surface of the microelectronic device. For chip-scale assemblies, the frame footprint surface area may be no greater than about 1.2 times that of the front surface area of the microelectronic device. In some instances, the frame may have a footprint surface area about equal to or less than the front surface area of the microelectronic device. In addition, for high pitch applications, neighboring pads and/or terminals may be no more than about 1 mm, preferably no more than about 0.1 mm, from each other. In some instances, pads and/or terminals may be arranged so that they are present in a high density per unit area. For example, the pads may be present in a density greater than about 100 posts per square centimeter. In some instances, a density of greater than about 400 pads per square centimeters can be achieved. Furthermore, to reduce excessive package or assembly height, the wall sections of the inventive frame or package may be no more than twice the device height.

A plurality of packages described above may be stacked to form a microelectronic assembly. For example, FIG. 1B depicts an assembly 1000 formed from stacking an upper package 1U on a lower package 1L. The exterior surface 216A of the base section 212A of the upper package 1U is placed in facing relationship to the roof surfaces 228B and 230B of the lower package 1L. As the packages 1U and 1L are substantially identical in construction, folds 204A and 206A of package 1U are aligned with folds 202A and 208B of package 1L.

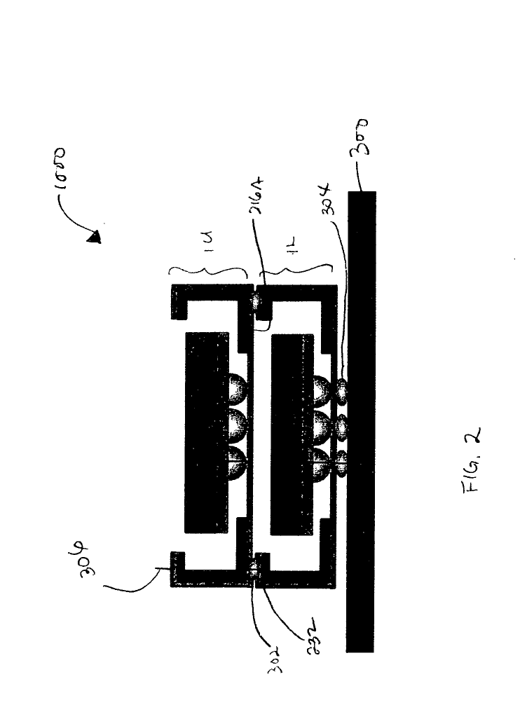

Optionally, additional terminals are provided on portions of exterior surface 216A overlying roof surface 228B and 230B such that packages 1U and 1L are in electrical communication with one another. For example, FIG. 2 depicts in side view the assembly 1000 of FIG. 1B bonded to a circuit board 300 and electrical connections associated therewith. Conductive members are strategically placed so as to provide electrical between the packages 1U and 1L and the circuit board 300. For example, conductive members in the form of metal balls 302 are placed between the exterior surface 216A and terminals 232B, 234B to provide electrical communication between packages 1U and 1L. Similarly, balls 304 are placed between the lower package 1L and the substrate 300, so as to provide electrical communication therebetween. Exemplary conductive paths of the assembly are indicated at 306.

Thus, it should be apparent that metal-clad sheets used in the invention (also referred to as single or double-metal tape) serve at least an electrical function. When no additional supporting structure is provided, the metal-clad sheets may also serve a mechanical function.

Metal-clad sheets suitable for use in the invention are typically each comprised of a base film of a dielectric material having parallel major surfaces, at least one of which contains electrically conductive regions. The electrically conductive regions may serve, e.g., as pads, terminals, or other parts of electrical paths. The dielectric material may be selected according to its functionality. In addition, depending on the material used and the handling requirements, the base film may be flexible, semi-flexible or substantially rigid. For example, when high rigidity, hardness, and/or high temperature dimensional stability is required, the dielectric material may be comprised of a ceramic material. Exemplary ceramic materials include single or mixed metal oxides such as aluminum or silicon oxides, nitrides, and carbides.

However, when flexibility is desired, polymeric materials may be used as the dielectric material. Base polymeric films may be substantially inextensible. Polyimide, for example, is a high performance polymer that has a number of desirable properties for advanced electronic applications. For example, polyimide films have a high degree of thermal stability, low shrinkage, reasonably high strength and modulus, low dissipation factor and good dielectric strength. In addition, polyimides are chemically stable, and withstand harsh chemical environments associated with circuit board processing. Suppliers of polyimide base film include: E.I. DuPont de Nemours & Co., Ube Industries, Ltd., and Kaneka Corporation.

Other polymeric materials include, but are not limited to, polyesters such as polyethylene terephthalate and polyethylene naphthalate, polyalkanes such as polyethylene, polypropylene and polybutylene, halogenated polymers such as partially and fully fluorinated polyalkanes and partially and fully chlorinated polyalkanes, polycarbonate, epoxies, and polysiloxanes.

In some instances, the dielectric material may be formed from a combination of polymeric and ceramic materials. For example, fiberglass laminates that optionally contain bismaleimide triazine (BT) may serve as the base film. Other composite materials may be used as well. Base film thickness may vary, but are, in general, about 5 μm to about 500 μm. In some instances, polymeric films may have a thickness on the order of about 20 μm to about 100 μm. In particular, polyimide films are commercially available 12.5 μm to 125 μm, although 25 μm and 50 μm films are most common.

In addition, as discussed above, each sheet generally has at least one major surface that contains electrically conductive regions. Such regions are comprised of an electrically conductive material. Typically, the regions are made from one or more metals. For example, a conductive region may be comprised of solid copper or a composite composition containing copper particles. Additional metals suitable for use in the invention include, for example, gold, silver, nickel, tin, chromium, iron, aluminum, zinc, combinations thereof, and alloys of any of the foregoing such as brass, bronze, and steel. In some instances, a surface layer may be provided over a base conductive layer of the electrically conductive regions, wherein the surface and base layers have differing compositions. For example, a highly conductive coating such as gold, gold/nickel, gold/osmium or gold/palladium, may be coated on a less conductive material. In addition or in the alternative, a base layer may be plated with a wear resistant coating such as osmium, chromium or titanium nitride.

When a support structure is used, the structure is typically comprised of substantially rigid material. In addition, the support structure is generally formed from an electrically insulating material when electrical paths of the frame are placed in contact therewith. Thus, ceramic material and/or rigid polymeric materials may be used. However, metallic support structures may be used in instances where the support structure also serves as an electrical path or where the support structure is electrically isolated from the electrical paths of the frame. In some instances, a metallic support structure may be used as a ground layer for signal improvement.

As alluded to above, an alignment mechanism may be provided for aligning the inventive frame with other items such as a circuit board, a microelectronic device, and/or other packages. In general, aligning mechanisms or apparatuses known in the art, e.g., mating features, clips, clamps, guides (mechanical, optical, electronic, or magnetic), devices used in metrology, etc., may be used to facilitate proper positioning of the inventive frame relative to other items. For example, at least one set of male and female mating features may be included to facilitate stacking. Optionally, a locking mechanism may be used as well. The locking mechanism may be the same as or different from the aligning mechanism.

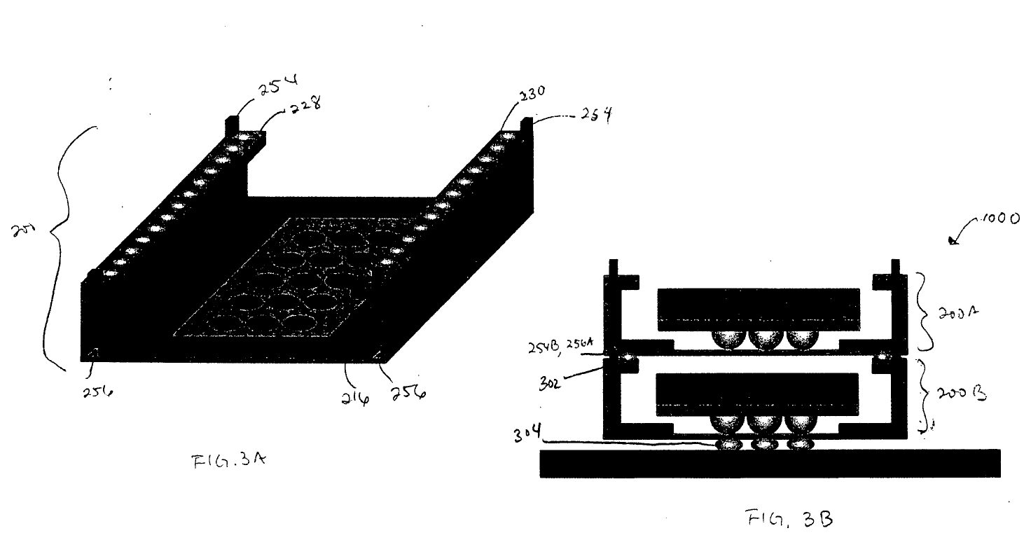

FIG. 3 illustrates an exemplary frame of the invention having a locking mechanism. In general, FIG. 3A depicts in perspective view a frame 200 that is substantially identical to the frame depicted in FIG. 1 except that it includes a mechanism for aligning the frame in the form of mating male and female features. Male features 254 are provided as an integral part of the supporting structure 250 of the frame 200. Accordingly, the male features may be formed from the same material as the frame. However, the male features may be provided discrete items as well. As a result, the male features and the frame may be formed from different materials. In any case, each feature protrudes from an exterior corner of a roof surface 228, 230. Similarly, female features 256 are provided as cavities within corners of the exterior base surface 216.

As shown, the male features 256 of mating features may be provided in the shape of rectangular blocks. However, other shapes may be advantageously used as well. For example, the male feature may be provided in the shape of a post that has a tapered profile such that the tip thereof has a smaller cross-sectional area than the base thereof. Exemplary shapes having a tapered profile include tetrahedrons and pyramids. In addition, an axially symmetric post may be used. Exemplary axially symmetric shapes include cones, truncated or otherwise, cylinders and hemispheres and spheres. A post may be either elongate or squat along the axis extending from it base to its tip. Less commonly, male features may have a narrow region between tip and base thereof. The narrow region may have a smaller cross-sectional area than either the tip or the base. For example, cooling tower shaped posts may be used. Hourglass-shaped posts may be used as well. In any case, when a plurality of male features is used, they may have the same shape and/or size. However, posts of different sizes and shapes may be used as well.

Typically, female features 256 will have a shape and construction complementary to that of the male feature 254. However, non-complementary shapes may be used as well. In any case, mating features may be located on the exterior surface of the base and at least one roof surface. For example, when the frame is constructed such that the exterior base surface faces a roof surface of another item, male and female mating features may be provided on the base and roof surfaces, respectively. In the alternative, the male and female mating feature may be swapped in position. Furthermore, both male and female mating features may be provided on a single surface.

FIG. 3B depicts in side view an assembly 1000 of stacked packages 1U and 1L formed from identical frames 200A and 200B. The assembly 1000 is similar to that depicted in FIG. 2 in that it is bonded to a circuit board 300 via balls 304. In addition, electrical communication is provided between package 1U and 1L through balls 302. However, male mating features 254B of the lower package 1L are inserted into female mating features 256A of the upper package 1U. As a result, the frames 200A and 200B are aligned and locked in place.

The inventive frame may include a lead-frame. In general, the term “lead-frame” refers to a metallic element that is typically self-supporting. That is, a lead-frame will not under ordinary gravitational forces permanently deform under its own weight, and may support additional forces associated with the formation of the inventive packages and assemblies. Lead-frames generally incorporate terminals and strips of relatively thick metal connecting the terminals to bus bars formed integrally with the strips and terminals. Lead-frames may be fabricated by conventional metal working processes using dies to punch out unwanted areas from a metal sheet, or by etching a metal sheet. The lead-frame may be assembled with a microelectronic device such as a semiconductor chip, and the contacts of the chip are connected to individual metallic strips so that the metallic strips serve as leads connecting the contacts of the chip to the terminals. In some instances, lead-frames formed from extremely thin metal strips, typically less than 50 micrometers thick. In some instances, lead-frames may be formed from metal strips having a thickness of less than about 25 micrometers.

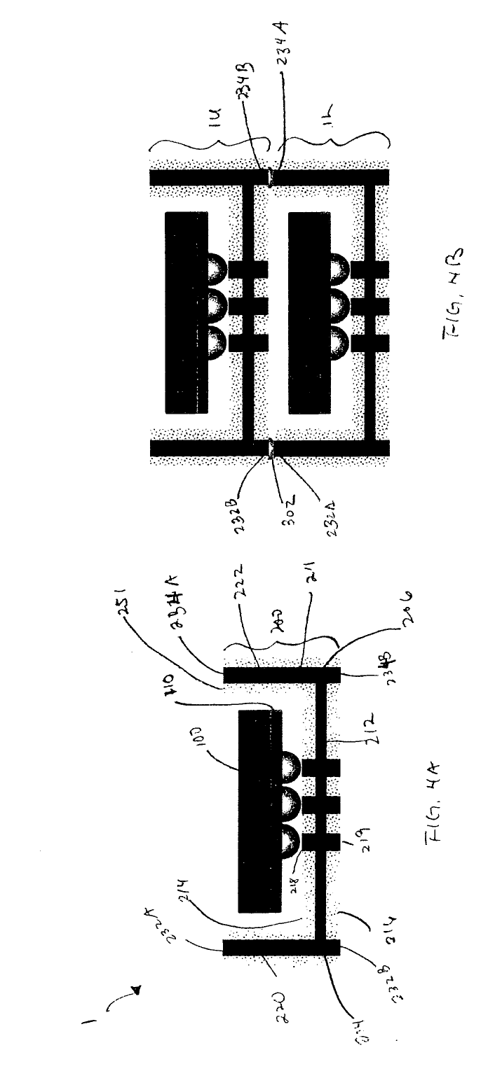

FIG. 4 depicts microelectronic packages that employ lead-frames. In FIG. 4A, a single package 1 is shown. Like the package depicted in FIG. 1, unit is provided that includes a microelectronic device 100 and a substrate 110 as well as a frame 200. In general, any microelectronic device 100 and substrate 110 suitable for use with the packages depicted in FIG. 1 may be used in the packages in FIG. 4.

Unlike the frames of FIG. 1, the frame 100 of FIG. 4 includes a lead-frame 211 that, except for selected portions thereof, e.g., those portions that serve as terminals and pads for the frame, is entirely covered by an optional molded covering 251. In some instances, the molded covering provides substantial additional rigidity to the frame 100. In addition or in the alternative, the molded covering 251 may serve as an electrically insulating or protective barrier. In any case, the lead-frame 211 in combination with the molded covering 251 form a unitary member that includes a base section 212 located between intersections 204 and 206. Opposing interior and exterior surfaces are indicated at 214 and 216, respectively. A plurality of dual directional prongs extend perpendicularly from the portion of the lead-frame in the base section 212. The prongs each terminate in one end at electrically conductive device-attachable pads 218 on the interior surface 214 of the base section 212 and in another end at terminals 219 on the exterior surface 216 of the base section.

The lead-frame 211 also includes parallel wall sections. First and second parallel wall sections, indicated at 220 and 222, respectively, coextend perpendicularly and in a dual direction manner from base section 212. While the first wall section 220 contacts base section 212 at intersection 204, the wall section 220 lies between terminals 232A and 232B. Similarly, the second wall section 222 contacts base section 212 at intersection 206 and is disposed between terminals 234A and 234B.

As shown in FIG. 4B, a plurality of packages 1U and 1L may be stacked in a manner similar to that depicted in FIG. 1 so as to provide electrical communication therebetween through flattened spheres 302. For example, terminals 232B of package 1U is placed over terminals 232A of package 1L. Similarly, terminals 234B of package 1U is placed over terminals 234A of package 1L.

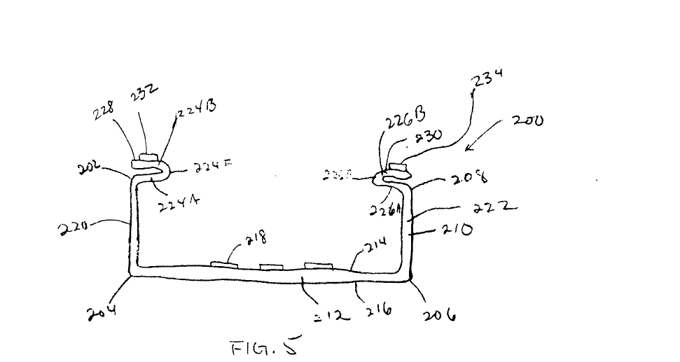

In addition, electrical communication between any terminal and any device-attachable pad may be routed through any of a number of ways. As depicted in FIG. 4, an electrical path may represent a portion of a lead-frame located almost entirely within the unitary member. Alternatively, as depicted in FIG. 5, the path may be exposed and/or located entirely on a surface of the unitary member. In some instances, at least portions of the path may avoid physical contact with the unitary member. For example, lead or wire bonds separable from the frame may be used.

The frames of the invention may have additional shapes and/or geometries that differ from those shown in FIGS. 1-4. FIG. 5 depicts in side view an exemplary frame of the invention formed from a rigid via-free single-metal-clad sheet without a supporting structure. Like the frame depicted in FIG. 1, the frame 200 of FIG. 5 is formed from a unitary sheet 210 having four 90-degree folds, indicated at 202, 204, 206, and 208. Accordingly, the sheet 210 includes a base section 212 located between folds 204 and 206 and electrically conductive device-attachable pads 218 on an interior base surface 214. In addition, the sheet 210 also includes parallel wall sections 220 and 222 coextending perpendicularly from base section 212. The first wall section 220 is located between folds 202 and 204, and the second wall section 222 is located between folds 206 and 208.

Like the frame shown in FIG. 1, the frame shown in FIG. 5 includes first and second inward cantilevered sections, indicated at 224A and 226A, respectively, that extend toward each other and perpendicularly from 90-degree folds 202 and 208. Instead of terminating at edges, sections 224A and 226A terminate at 180-degree folds indicated at 224F and 226F. Originating from fold 224F is a first outward cantilevered section 224B. Similarly, a second outward cantilevered section 226B originates from fold 226F. Sections 224B and 226B extend away from each other. A first substantially planar roof surface 228 is supported by cantilevered section 224B, and a second substantially planar roof surface 230 is supported by cantilevered section 226B. First terminals 232 are located on the first roof surface 228, and second terminals 234 are located on the second roof surface 230.

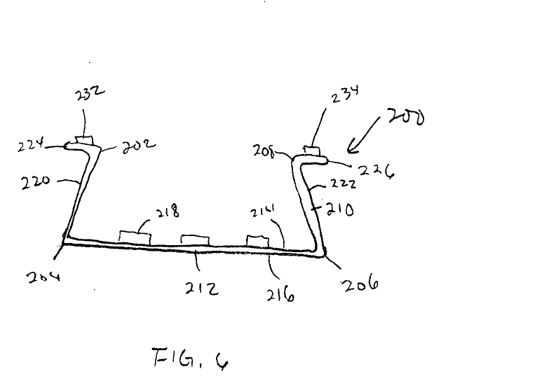

FIG. 6 depicts in side view an exemplary frame of the invention similar to that depicted in FIG. 5 except that it has a double-Z shape. The frame 200 is formed from a unitary sheet 210 having folds of substantially identical acute angles, indicated at 202, 204, 206, and 208. Accordingly, the sheet 210 includes a base section 212 located between folds 204 and 206 and electrically conductive device-attachable pads 218 on an interior base surface 214. In addition, the sheet 210 also includes inwardly extending wall sections 220 and 222. The first wall section 220 is located between folds 202 and 204, and the second wall section 222 is located between folds 206 and 208.

The frame also includes first and second cantilevered sections, indicated at 224 and 226, respectively, that extend away from each other. A first substantially planar roof surface 228 is supported by cantilevered section 224, and a second substantially planar roof surface 230 is supported by cantilevered section 226. The roof surfaces are at least substantially coplanar and parallel to interior base surface 214. First terminals 232 are located on the first roof surface 228, and second terminals 234 are located on the second roof surface 230.

Thus, the invention provides previously unknown advantages in the art of microelectronic packaging. As an initial matter, the invention may easily be adapted to conform to or incorporate industry standard such as JEDEC ball-out designs. In addition, the invention combines area array technology with side connections. Furthermore, dedicated packages for stacking are not needed because the packages and assemblies may be assembled during the last stage of standard surface mount techniques. Thus, individual frames and devices may be provided assembled in different orders. For example, a two-package stacked assembly may be formed by first placing a first device in a first frame to form a first package, followed by placing a second frame on the first package, followed by placing a second device in the second frame to form the stacked assembly. Alternatively, the two-package stacked assembly may be formed by first forming the both the first and second packages and then stacking the second package on the first package.

Variations of the present invention will be apparent to those of ordinary skill in the art. For example, while the frames depicted in FIGS. 1-6 generally have a rectangular footprint and are box-like in overall shape, other frames that have a nonrectangular footprint or a non-box-like overall shape may be advantageously used as well. In addition, solders, conductive pastes, and other electrical connection technologies known in the art may be employed to effect electrical communication between any items of the invention. Similarly, surface mount technologies known in the art may be employed. Furthermore, the invention is compatible with encapsulant or molding technologies known in the art. Additional variations of the invention may be discovered upon routine experimentation without departing from the spirit of the present invention.

It is to be understood that, while the invention has been described in conjunction with the preferred specific embodiments thereof, the foregoing description merely illustrate and not limit the scope of the invention. Numerous alternatives and equivalents exist which do not depart from the invention set forth above. Other aspects, advantages, and modifications within the scope of the invention will be apparent to those skilled in the art to which the invention pertains.

All patents mentioned herein are hereby incorporated by reference in their entireties.

1. A frame for packaging a microelectronic device, comprising:
a unitary member, comprising
a base section having opposing interior and exterior planar base surfaces,
first and second parallel wall sections each extending perpendicularly from the base section, and
first and second substantially planar roof surfaces facing away from the base section and supported by the first and second wall sections, respectively;
a plurality of electrically conductive device-attachable pads on the interior base surface; and
a plurality of first and second terminals located on the first and second roof surfaces, respectively, in electrical communication with the device-attachable pads.

2. The frame of claim 1, wherein the unitary member further comprises a first cantilevered section extending from the first wall section toward the second wall section, and supporting the first roof surface.

3. The frame of claim 2, wherein the unitary member further comprises a second cantilevered section extending from the second wall section toward the first wall section and supporting the second roof surface.

4. The frame of claim 3, wherein the unitary member has a C-shape.

5. The frame of claim 1, wherein the roof surfaces are substantially coplanar.

6. The frame of claim 1, wherein the device-attachable pads are arranged in a pad array.

7. The frame of claim 1, wherein the first and second terminals are arranged in first and second arrays, respectively.

8. The frame of claim 7, wherein the first and second arrays exhibit mirror symmetry.

9. The frame of claim 1, further comprising an alignment mechanism for aligning the frame for stacking.

10. The frame of claim 9, wherein the alignment mechanism includes at least one set of mating features located on the exterior base surface and at least one roof surface.

11. The frame of claim 10, wherein at least one mating feature on the at least one roof surface is male.

12. The frame of claim 10, wherein at least one mating feature on the at least one roof surface is female.

13. The frame of claim 1, wherein at least one terminal is in electrical communication with at least one device-attachable pad via an electrical path located at least partially within the member.

14. The frame of claim 13, wherein the electrical path represents a portion of a lead-frame.

15. The frame of claim 1, further comprising a plurality of terminals on the exterior base surface.

16. The frame of claim 1, wherein at least one terminal is in electrical communication with at least one device-attachable pad via an exposed electrical path.

17. The frame of claim 1, comprising a polymeric material.

18. The frame of claim 17, wherein the polymeric material is a molded plastic.

19. The frame of claim 17, wherein the polymeric material represents a portion of a single-metal-clad sheet.

20. The frame of claim 17, wherein the polymeric material represents a portion of a double-metal-clad sheet.

21. A microelectronic package, comprising:
a microelectronic device having opposing front and surfaces separated by a device height and a plurality of electrical contacts on the front surface;
a unitary member, comprising a base section having opposing interior and exterior planar base surfaces, first and second parallel wall sections each extending from the base section, and first and second substantially planar roof surfaces facing away from the base section and supported by first and second wall sections, respectively, wherein the roof surfaces are separated by a gap sized to allow through passage of the device while the front device surface is parallel to the interior base surface;
a plurality of device-attachable regions on the first planar base surface and in electrical communication with the contacts of the microelectronic device; and
a plurality of terminals located on the roof surfaces and in electrical communication with the device-attachable regions.

22. The microelectronic package of claim 21, wherein the front surface of the device faces towards the interior base surface.

23. The microelectronic package of claim 22, wherein the device is rigidly attached to the base section of the frame in a flip-chip configuration.

24. The microelectronic package of claim 21, wherein the front surface of the device faces away from the interior base surface.

25. The microelectronic package of claim 21, wherein the device is wire bonded or lead bonded to the frame.

26. The microelectronic package of claim 21, wherein the device is movable relative to the device-attachable regions to a substantial fatigue relieving degree.

27. The microelectronic package of claim 21, wherein the wall sections are no more than twice the device height.

28. A multi-device microelectronic assembly comprising a plurality of microelectronic packages of claim 21 in electrical communication with each another.

29. The microelectronic assembly of claim 28, wherein the microelectronic packages are stacked.

30. The microelectronic assembly of claim 28, wherein the microelectronic packages are substantially identical.

31. A method for producing a microelectronic package, comprising:
(a) providing a frame for packaging a microelectronic device, comprising:
a unitary member, comprising
a base section having opposing interior and exterior planar base surfaces,
first and second parallel wall sections each extending perpendicularly from the base section, and
first and second substantially planar roof surfaces facing away from the base section and supported by the first and second wall sections, respectively,
a plurality of electrically conductive device-attachable pads on the interior base surface, and
a plurality of first and second terminals located on the first and second roof surfaces, respectively, in electrical communication with the device-attachable pads; and
(b) electrically attaching electrical contacts on a front surface of a microelectronic device to the device-attachable pads on the interior surface of the frame.

32. The method of claim 31, wherein the electrical contacts are rigidly attached to the device-attachable pads in a flip-chip configuration.

33. The method of claim 31, wherein the electrical contacts are movably attached to the device-attachable pads.

34. The method of claim 31, further comprising (c) introducing an electrically insulating material between the microelectronic device and the base section of the frame.

35. The method of claim 34, wherein the electrically insulating material is compliant.

36. The method of claim 34, wherein the electrically insulating material is rigid.
